(19) United States
(12) Patent Application Publication
(10) Pub. No.: US 2023/0214549 A1
(43) Pub. Date: Jul. 6, 2023

(54) SOURCE OPERATOR RELATED TECHNIQUES FOR USE IN STREAMING ANALYTICS

(71) Applicant: International Business Machines Corporation, Armonk, NY (US)

(72) Inventors: Henry Chiu, San Jose, CA (US); Jingdong SUN, Rochester, MN (US); Bradley William Fawcett, Byron, MN (US); Jason A. Nikolai, Rochester, MN (US); Paul Gerver, Rochester, MN (US)

(21) Appl. No.: 17/647,180

(22) Filed: Jan. 6, 2022

(51) Int. Cl. G06F 30/20

(52) U.S. Cl. CPC G06F 30/20

(57) ABSTRACT

A computer system where pre-existing virtual models of physical assets, processes and/or computer system supply input data streams to a streaming analytics application through respective stream operators. The streaming analytics application uses this input data to make improvements to the code and/or configuration of the streaming analytics application itself and/or to create newly-created virtual model(s).

### BACKGROUND

The present invention relates to the following fields: the creation and/or refinement of models made of computer code and data (herein referred to as “virtual models,” or, more simply, as “models”) and streaming analytics.

There are various types of models as follows: (i) virtual physical asset models made to match a physical asset (for example, a vehicle having serial number 1234567890) or type of physical asset (for example, a type of vehicle having some given make and model); (ii) virtual process models made to match an actual instantiation of a process (for example, the processes occurring in an auto assembly plant located at 123 Main Street, Anytown USA) or a type of process (for example, the Haber process used to make a certain chemical); and (iii) virtual system models made to match an instantiation of a system (for example, a computer data storage device having MAC address 0987654321) or a type of system (for example, a storage system having a set of predetermined spec's, such as capacity and transfer speeds).

For purposes of this document, a “digital twin” is hereby defined as follows: any model that matches an actual instantiation of a physical asset, a process, a system or any combination of these types of digital twin. In the foregoing definitions, “matching” does not mean that every possible attribute is tracked by the corresponding virtual model. For example, if a vehicle gets a 1 millimeter long scratch on its bumper, then this development would likely not be tracked by the corresponding digital twin of the vehicle. “Matching” means “sufficiently matching” as those of skill in the art of virtual models understand that term when they make and use virtual models.

A “cross-cycle virtual model” is hereby defined, for purposes of this document as any virtual model that tracks a physical asset, a process, or system across its life cycle.

“Streaming analytics” is hereby defined, for purposes of this document, to be any set of machine logic (for example, software) that analyzes and performs actions on real-time data though the use of continuous queries.

“Source operators” are hereby defined, for purposes of this document, as any set of machine logic (for example, software) that connects an external data source (for example, a stream of digital output data from an Internet of Things (IoT) sensor) to a computer system that performs streaming analytics. Source operators can be thought of as a data interface between streaming analytics systems and their input data streams. Typically, the source operator performs functions such as ensuring that the incoming data is coming in from the correct sources, making sure that the incoming data streams are coming in according to the correct protocols and/or formats, and making sure that the speed and/or continuity of the incoming data streams are correct.

### SUMMARY

According to an aspect of the present invention, there is a method, computer program product and/or system that performs the following operations (not necessarily in the following order): (i) receiving a streaming analytics application that is configured to receive a plurality of data stream(s) respectively from a set of source operator(s); (ii) connecting, in data communication, a set of pre-existing virtual model(s) respectively to the set of source operator(s); (iii) receiving, by the streaming analytics application, a set of input data stream(s) respectively from the pre-existing virtual model(s) as simulated real-time data in the streaming analytics application; and (iv) refining the code and/or configurable operating parameters of the streaming analytics application based on the simulated real-time data received through the set of source operator(s) and from the pre-existing set of virtual model(s).

According to a further aspect of the present invention, there is a method, computer program product and/or system that performs the following operations (not necessarily in the following order): (i) receiving a streaming analytics application that is configured to receive a plurality of data stream(s) respectively from a set of source operator(s); (ii) connecting, in data communication, a set of pre-existing virtual model(s) respectively to the set of source operator(s); (iii) receiving, by the streaming analytics application, a set of input data stream(s) respectively from the pre-existing virtual model(s) as simulated real-time data in the streaming analytics application; and (iv) creating, by the streaming analytics application, a newly-created virtual model, based on the simulated real-time data received through the set of source operator(s) and from the pre-existing set of virtual model(s).

According to a further aspect of the present invention, there is a method, computer program product and/or system that performs the following operations (not necessarily in the following order): (i) receiving a streaming analytics application that is configured to receive a plurality of data stream(s) respectively from a set of source operator(s); (ii) connecting, in data communication, a set of pre-existing virtual model(s) respectively to the set of source operator(s); (iii) receiving, by the streaming analytics application, a set of input data stream(s) respectively from the pre-existing virtual model(s) as simulated real-time data in the streaming analytics application; (iv) refining the code and/or configurable operating parameters of the streaming analytics application based on the simulated real-time data received through the set of source operator(s) and from the pre-existing set of virtual model(s); and (v) creating, by the streaming analytics application, a newly-created virtual model, based on the simulated real-time data received through the set of source operator(s) and from the pre-existing set of virtual model(s).

### BRIEF DESCRIPTION OF THE DRAWINGS

FIG. 1 is a block diagram view of a first embodiment of a system according to the present invention;

FIG. 2 is a flowchart showing a first embodiment method performed, at least in part, by the first embodiment system;

FIG. 3 is a block diagram showing a machine logic (for example, software) portion of the first embodiment system;

FIGS. 4A to 4C are block diagrams helpful in understanding various embodiments of the present invention;

FIG. 5 is a block diagram helpful in understanding various embodiments of the present invention; and

FIG. 6 is a block diagram helpful in understanding various embodiments of the present invention.

### DETAILED DESCRIPTION

Some embodiments of the present invention use digital twin models as configurable source operators to simulate and optimize streams jobs under various workload conditions. The number of source operators can be changed, and parameters to source operators can be dynamically changed by users to see how well the application performs with different workloads. Over time, the optimal job configuration and resource usage can be determined and cached. When the application is running with real input devices, the streams system can change to a known job configuration that runs optimally when a condition is met. The model included in the digital twin doesn't have to catch all changes to be a digital twin. Some embodiments of the present invention are directed to using a digital twin to simulate and optimize streams jobs. For the purposes of simulation, the models can but don't have to be updated with real-time information from the physical asset. Catching changes may improve the accuracy of the model. This Detailed Description section is divided into the following subsections: (i) The Hardware and Software Environment; (ii) Example Embodiment; (iii) Further Comments and/or Embodiments; and (iv) Definitions.

### I. The Hardware And Software Environment

The present invention may be a system, a method, and/or a computer program product at any possible technical detail level of integration. The computer program product may include a computer readable storage medium (or media) having computer readable program instructions thereon for causing a processor to carry out aspects of the present invention. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (for example, light pulses passing through a fiber-optic cable), or electrical signals transmitted through a wire.

A “storage device” is hereby defined to be anything made or adapted to store computer code in a manner so that the computer code can be accessed by a computer processor. A storage device typically includes a storage medium, which is the material in, or on, which the data of the computer code is stored. A single “storage device” may have: (i) multiple discrete portions that are spaced apart, or distributed (for example, a set of six solid state storage devices respectively located in six laptop computers that collectively store a single computer program); and/or (ii) may use multiple storage media (for example, a set of computer code that is partially stored in as magnetic domains in a computer's non-volatile storage and partially stored in a set of semiconductor switches in the computer's volatile memory). The term “storage medium” should be construed to cover situations where multiple different types of storage media are used.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

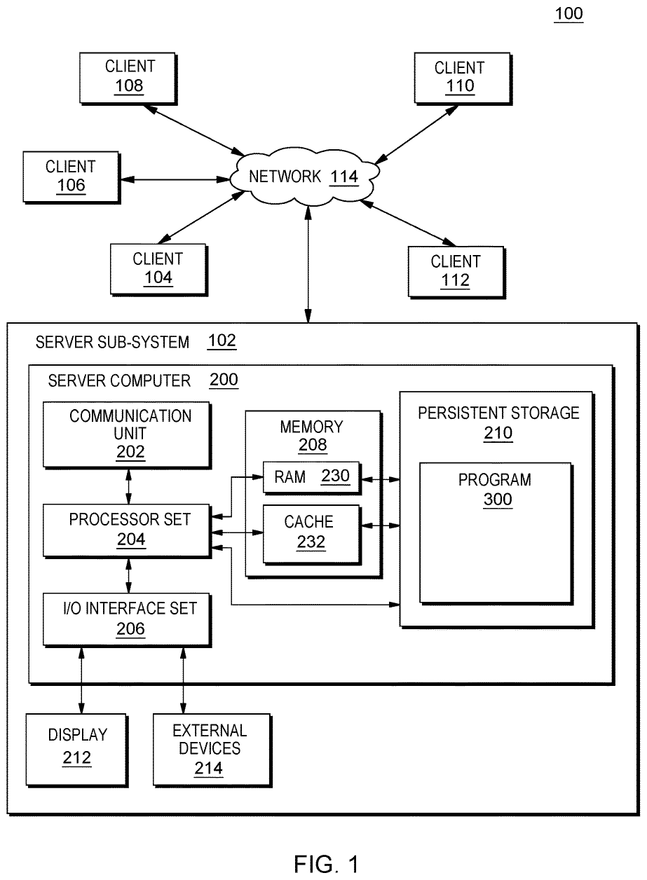

As shown in FIG. 1, networked computers system 100 is an embodiment of a hardware and software environment for use with various embodiments of the present invention. Networked computers system 100 includes: server subsystem 102 (sometimes herein referred to, more simply, as subsystem 102); client subsystems 104, 106, 108, 110, 112; and communication network 114. Server subsystem 102 includes: server computer 200; communication unit 202; processor set 204; input/output (I/O) interface set 206; memory 208; persistent storage 210; display 212; external device(s) 214; random access memory (RAM) 230; cache 232; and program 300.

Subsystem 102 may be a laptop computer, tablet computer, netbook computer, personal computer (PC), a desktop computer, a personal digital assistant (PDA), a smart phone, or any other type of computer (see definition of “computer” in Definitions section, below). Program 300 is a collection of machine readable instructions and/or data that is used to create, manage and control certain software functions that will be discussed in detail, below, in the Example Embodiment subsection of this Detailed Description section.

Subsystem 102 is capable of communicating with other computer subsystems via communication network 114. Network 114 can be, for example, a local area network (LAN), a wide area network (WAN) such as the Internet, or a combination of the two, and can include wired, wireless, or fiber optic connections. In general, network 114 can be any combination of connections and protocols that will support communications between server and client subsystems.

Subsystem 102 is shown as a block diagram with many double arrows. These double arrows (no separate reference numerals) represent a communications fabric, which provides communications between various components of subsystem 102. This communications fabric can be implemented with any architecture designed for passing data and/or control information between processors (such as microprocessors, communications and network processors, etc.), system memory, peripheral devices, and any other hardware components within a computer system. For example, the communications fabric can be implemented, at least in part, with one or more buses.

Memory 208 and persistent storage 210 are computer-readable storage media. In general, memory 208 can include any suitable volatile or non-volatile computer-readable storage media. It is further noted that, now and/or in the near future: (i) external device(s) 214 may be able to supply, some or all, memory for subsystem 102; and/or (ii) devices external to subsystem 102 may be able to provide memory for subsystem 102. Both memory 208 and persistent storage 210: (i) store data in a manner that is less transient than a signal in transit; and (ii) store data on a tangible medium (such as magnetic or optical domains). In this embodiment, memory 208 is volatile storage, while persistent storage 210 provides nonvolatile storage. The media used by persistent storage 210 may also be removable. For example, a removable hard drive may be used for persistent storage 210. Other examples include optical and magnetic disks, thumb drives, and smart cards that are inserted into a drive for transfer onto another computer-readable storage medium that is also part of persistent storage 210.

Communications unit 202 provides for communications with other data processing systems or devices external to subsystem 102. In these examples, communications unit 202 includes one or more network interface cards. Communications unit 202 may provide communications through the use of either or both physical and wireless communications links. Any software modules discussed herein may be downloaded to a persistent storage device (such as persistent storage 210) through a communications unit (such as communications unit 202).

I/O interface set 206 allows for input and output of data with other devices that may be connected locally in data communication with server computer 200. For example, I/O interface set 206 provides a connection to external device set 214. External device set 214 will typically include devices such as a keyboard, keypad, a touch screen, and/or some other suitable input device. External device set 214 can also include portable computer-readable storage media such as, for example, thumb drives, portable optical or magnetic disks, and memory cards. Software and data used to practice embodiments of the present invention, for example, program 300, can be stored on such portable computer-readable storage media. I/O interface set 206 also connects in data communication with display 212. Display 212 is a display device that provides a mechanism to display data to a user and may be, for example, a computer monitor or a smart phone display screen.

In this embodiment, program 300 is stored in persistent storage 210 for access and/or execution by one or more computer processors of processor set 204, usually through one or more memories of memory 208. It will be understood by those of skill in the art that program 300 may be stored in a more highly distributed manner during its run time and/or when it is not running. Program 300 may include both machine readable and performable instructions and/or substantive data (that is, the type of data stored in a database). In this particular embodiment, persistent storage 210 includes a magnetic hard disk drive. To name some possible variations, persistent storage 210 may include a solid state hard drive, a semiconductor storage device, read-only memory (ROM), erasable programmable read-only memory (EPROM), flash memory, or any other computer-readable storage media that is capable of storing program instructions or digital information.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

### II. Example Embodiment

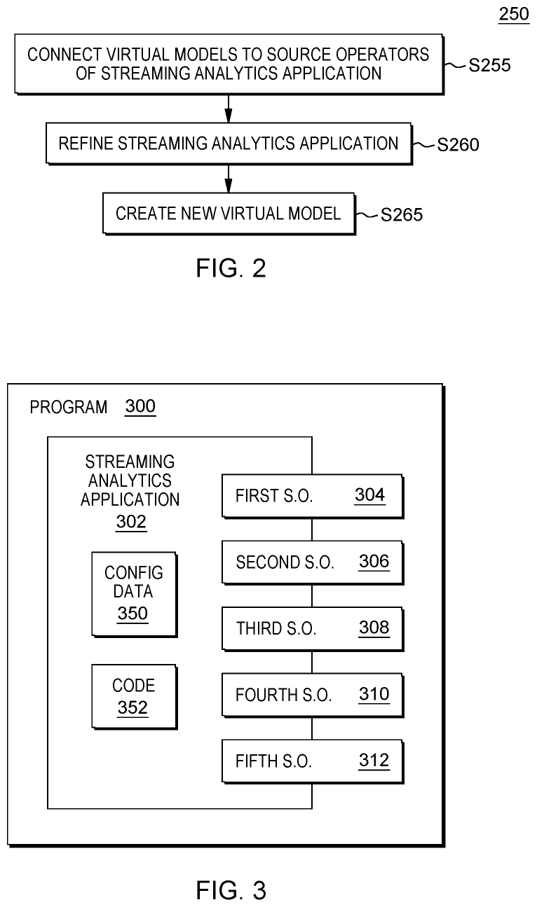

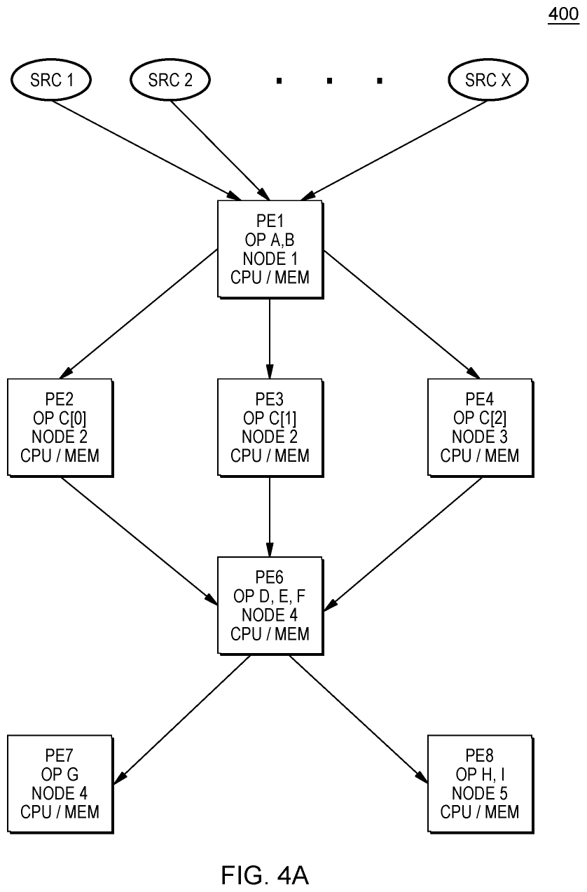

As shown in FIG. 1, networked computers system 100 is an environment in which an example method according to the present invention can be performed. As shown in FIG. 2, flowchart 250 shows an example method according to the present invention. As shown in FIG. 3, program 300 performs or controls performance of at least some of the method operations of flowchart 250. This method and associated software will now be discussed, over the course of the following paragraphs, with extensive reference to the blocks of FIGS. 1, 2 and 3.

Processing begins at operation S255, where source operators 304, 306, 308, 310 and 312 of streaming analytics application 302 are configured to respectively receive input data streams from pre-existing virtual models. More specifically: (i) first source operator 304 is configured to receive an input data stream from a virtual model (in this example, a digital twin type virtual model) hosted at client subsystem 104; (ii) second source operator 306 is configured to receive an input data stream from a virtual model (in this example, a digital twin type virtual model) hosted at client subsystem 106; (iii) third source operator 308 is configured to receive an input data stream from a virtual model (in this example, a digital twin type virtual model) hosted at client subsystem 108; (iv) fourth source operator 310 is configured to receive an input data stream from a virtual model (in this example, a digital twin type virtual model) hosted at client subsystem 110; and (v) fifth source operator 312 is configured to receive an input data stream from a virtual model (in this example, a digital twin type virtual model) hosted at client subsystem 112.

Processing proceeds to operation S260, where: (i) streaming analytics application 302 receives input data, in the form of simulated real-time data, from the pre-existing virtual models; and (ii) refines and optimizes configuration data 350 of the streaming analytics application and code 352 of the streaming analytics application based on the simulated real-time input data received from the pre-existing virtual models.

Processing proceeds to operation S265, where the streaming analytics application creates a newly-created virtual model based on the simulated real-time input data. The newly-created virtual model may now be distributed and used as appropriate.

### III. Further Comments and/or Embodiments

Some embodiments of the present invention may include one, or more, of the following operations, features, characteristics and/or advantages: (i) uses source operators of a streaming analytics application to receive input data from a pre-existing virtual model as simulated real-time data in the streaming analytics application in order to optimize the streaming analytics application; (ii) changing the number and/or types of virtual models providing input data to the source operators of the streaming analytics application in order to simulate different workloads that might be faced in future real world situations and/or contexts; (iii) configurable virtual models provide input data to the source operators of the streaming analytics application to generate different real world scenarios that might be expected to be encountered in the future; (iv) automatically generating a virtual model (for example, a digital twin type virtual model by the streaming analytics application based on the simulated streaming data received through the source operator(s) from the virtual model(s); (v) the streaming analytics application saves optimal job configurations for subsequent runs; (vi) creating a new virtual model (for example, a digital twin type virtual model) by the streaming analytics application based on the input data from the pre-existing virtual model(s) streaming data to and through the source operator(s); and/or (vii) setting up a real world physical asset, system and/or process that matches the new virtual model created by the streaming analytics application

As an example of item (vi) in the foregoing list, an IoT system may be created, created configured and put into operation as a real world instantiation, such that the number, type and configurations of the various IoT devices match a newly-created virtual system model of an IoT system that has been created by the streaming analytics application.

Some embodiments of the present invention may include one, or more, of the following operations, features, characteristics and/or advantages: (i) users create and upload virtual model(s) of a physical asset(s), system(s) and/or process(es) to steam data to, and through, source operator(s) in a streaming analytics application; (ii) the virtual model(s) act as a pseudo data generator for the streaming analytics application; (iii) herein, the pre-existing models that provide data to the streaming analytics application are herein sometimes referred to as “virtual model inputters”; (iv) each virtual model inputter may be described through the following attributes: (a) tuple schema, (b) tuple data range, (c) tuple rate and (d) criteria/condition; (v) the streaming analytics application automatically generates a newly-created model based on its analytical analysis of the data received from the virtual model inputter(s).

Some embodiments of the present invention may include one, or more, of the following operations, features, characteristics and/or advantages: (i) provides a dynamic solution for receiving dynamic input data at the source operators of a streaming analytics application; (ii) when considering the previous item on this list, consider that traditional source operators are static in that they pulls data from URL (uniform resource locator), database, file, or the like; (ii) streams developers can simulate different data and workloads by dynamically controlling the virtual models (for example digital twin type virtual models) that input data to source operators the source operators of the streaming analytics application; (iii) allows the number of virtual model inputters to be adjusted (for example, the number of virtual model imputters may be increased from 100 to 1000; (iv) system designer may specify the operating parameter values for each virtual model inputter (for example, half of the inputters run under Condition A, while other inputters are configured to run under Condition B); and/or (v) updates can be made to the newly-created virtual model that is created by the streaming analytics application as it analyzes various simulated streams jobs for cost effectiveness and throughput.

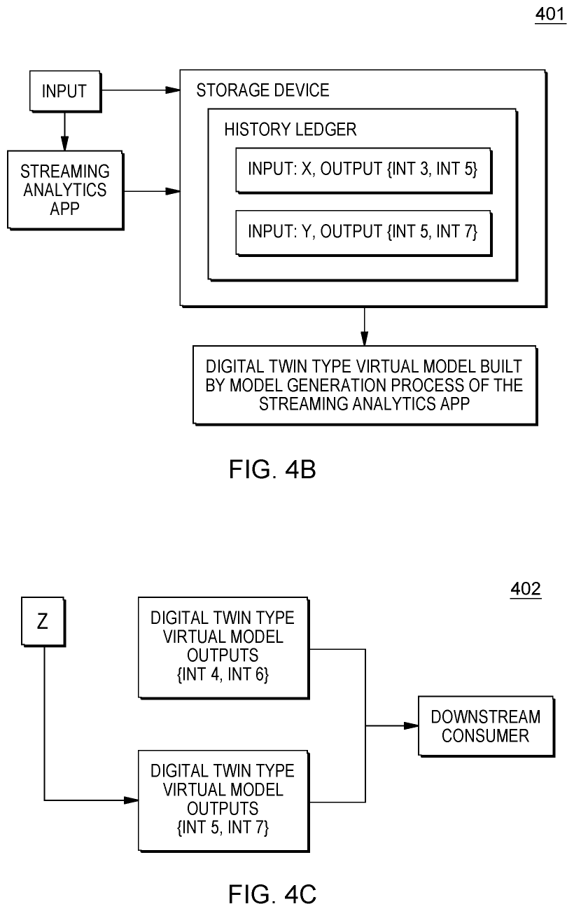

Some embodiments of the present invention may include one, or more, of the following operations, features, characteristics and/or advantages: (i) caching optimal job configurations based on simulated workload conditions, as shown in streams application diagram 400 (parallel width region=3) of FIG. 4A; (ii) different job topology may include attributes, such as: width of parallel regions, how operators are fused together into executable units and/or which nodes processing elements are placed to run; (iii) caching optimal resource usage to save on costs may include: number of cluster nodes used and/or central processing unit/memory requests and limits for processing elements; and/or (iv) streams system can change to known job configuration that runs optimally when similar conditions are later seen.

Creating digital twins from streams applications may include: (i) historical data can be used to create a model of an entire streams app; (ii) model generates data for simulation into other systems; (iii) model can generate pseudo-data, or accept input that computes real output results; (iv) twin can be built as different types of executable code; (v) for example, distributed streams app is converted to a non-distributed standalone program that can run on IoT devices; and/or (vi) acts as a preview of the distributed application's capability by running a light workload on a single device.

Diagram 401 of FIG. 4B represents a process of creating a digital twin model by a streaming analytics app.

Diagram 402 of FIG. 4C represents a process of using a digital twin model by a streaming analytics app.

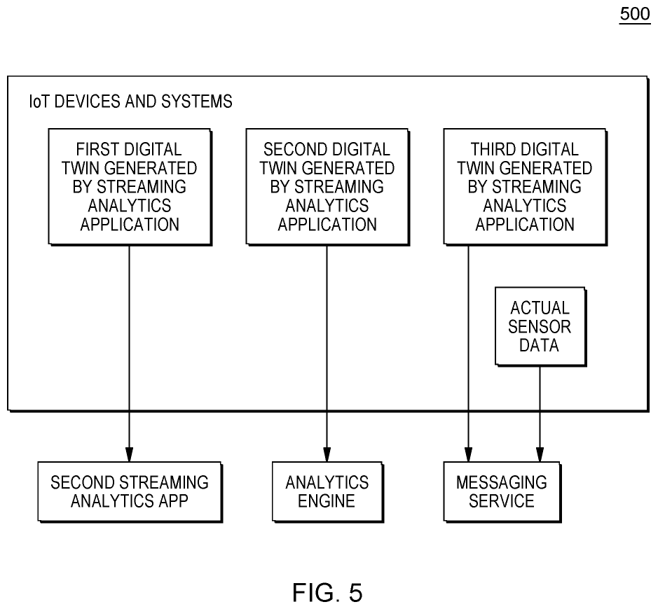

Diagram 500 of FIG. 5 represents streams digital twins deployed to IoT to mock, simulate and/or emulate edge analytics.

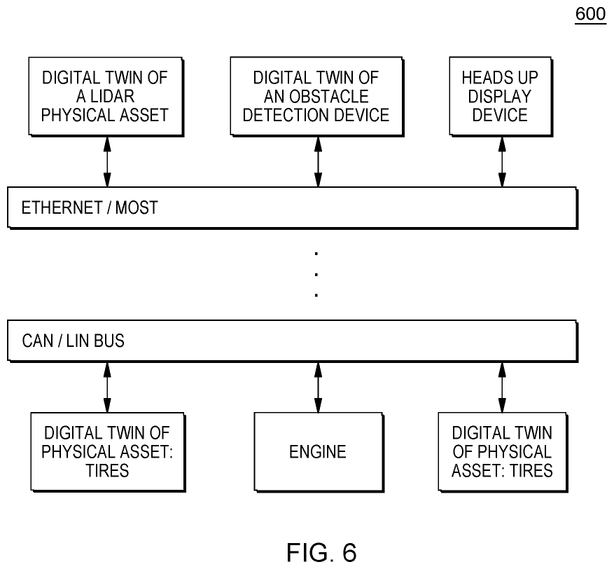

Diagram 600 of FIG. 6 represents an example of an autonomous car system containing multiple digital twin streams models.

A method for using a digital twin model in a streaming analytics system according to the present invention includes the following operations (not necessarily in the following order): (i) generating a digital twin model of an external data source (for example, an IoT sensor) that provides streaming data to a streaming analytics system (for example, a stream processing system); (ii) using the digital twin model as a source operator in the streaming analytics system, allowing for the simulation of various real-world use cases via configuration of the digital twin model; (iii) using additional digital twin models as additional source operators in the streaming analytics system, allowing for the simulation of workloads with differing numbers of source operators; and (iv) generating a digital twin model of the entire streaming analytics system and executing the digital twin model of the entire streaming analytics system on different target environments (for example, different IoT devices).

### IV. Definitions

Present invention: should not be taken as an absolute indication that the subject matter described by the term “present invention” is covered by either the claims as they are filed, or by the claims that may eventually issue after patent prosecution; while the term “present invention” is used to help the reader to get a general feel for which disclosures herein are believed to potentially be new, this understanding, as indicated by use of the term “present invention,” is tentative and provisional and subject to change over the course of patent prosecution as relevant information is developed and as the claims are potentially amended.

Embodiment: see definition of “present invention” above—similar cautions apply to the term “embodiment.”

And/or: inclusive or; for example, A, B “and/or” C means that at least one of A or B or C is true and applicable.

Including/include/includes: unless otherwise explicitly noted, means “including but not necessarily limited to.”

Module/Sub-Module: any set of hardware, firmware and/or software that operatively works to do some kind of function, without regard to whether the module is: (i) in a single local proximity; (ii) distributed over a wide area; (iii) in a single proximity within a larger piece of software code; (iv) located within a single piece of software code; (v) located in a single storage device, memory or medium; (vi) mechanically connected; (vii) electrically connected; and/or (viii) connected in data communication.

Computer: any device with significant data processing and/or machine readable instruction reading capabilities including, but not limited to: desktop computers, mainframe computers, laptop computers, field-programmable gate array (FPGA) based devices, smart phones, personal digital assistants (PDAs), body-mounted or inserted computers, embedded device style computers, application-specific integrated circuit (ASIC) based devices.

What is claimed is:

1. A computer-implemented method (CIM) comprising:
receiving a streaming analytics application that is configured to receive a plurality of data stream(s) respectively from a set of source operator(s);
connecting, in data communication, a set of pre-existing virtual model(s) respectively to the set of source operator(s);
receiving, by the streaming analytics application, a set of input data stream(s) respectively from the pre-existing virtual model(s) as simulated real-time data in the streaming analytics application; and
refining the code and/or configurable operating parameters of the streaming analytics application based on the simulated real-time data received through the set of source operator(s) and from the pre-existing set of virtual model(s).

2. The CIM of claim 1 wherein the set of pre-existing virtual model(s) includes a first virtual model corresponding to an Internet of Things (IoT) device.

3. The CIM of claim 2 wherein the first virtual model is a digital twin of a real world instantiation of an IoT device.

4. The CIM of claim 1 wherein each given virtual model of the set of pre-existing virtual model(s) is a digital twin that corresponds to a real world instantiation of a physical asset.

5. The CIM of claim 1 wherein each given virtual model of the set of pre-existing virtual model(s) is a digital twin that corresponds to a real world instantiation of a process.

6. The CIM of claim 1 wherein each given virtual model of the set of pre-existing virtual model(s) is a digital twin that corresponds to a real world instantiation of a computer system.

7. A computer-implemented method (CIM) comprising:
receiving a streaming analytics application that is configured to receive a plurality of data stream(s) respectively from a set of source operator(s);
connecting, in data communication, a set of pre-existing virtual model(s) respectively to the set of source operator(s);
receiving, by the streaming analytics application, a set of input data stream(s) respectively from the pre-existing virtual model(s) as simulated real-time data in the streaming analytics application; and
creating, by the streaming analytics application, a newly-created virtual model, based on the simulated real-time data received through the set of source operator(s) and from the pre-existing set of virtual model(s).

8. The CIM of claim 7 wherein the set of pre-existing virtual model(s) includes a first virtual model corresponding to an Internet of Things (IoT) device.

9. The CIM of claim 8 wherein the first virtual model is a digital twin of a real world instantiation of an IoT device.

10. The CIM of claim 7 wherein each given virtual model of the set of pre-existing virtual model(s) is a digital twin that corresponds to a real world instantiation of a physical asset.

11. The CIM of claim 7 wherein each given virtual model of the set of pre-existing virtual model(s) is a digital twin that corresponds to a real world instantiation of a process.

12. The CIM of claim 7 wherein each given virtual model of the set of pre-existing virtual model(s) is a digital twin that corresponds to a real world instantiation of a computer system.

13. A computer-implemented method (CIM) comprising:
receiving a streaming analytics application that is configured to receive a plurality of data stream(s) respectively from a set of source operator(s);
connecting, in data communication, a set of pre-existing virtual model(s) respectively to the set of source operator(s);
receiving, by the streaming analytics application, a set of input data stream(s) respectively from the pre-existing virtual model(s) as simulated real-time data in the streaming analytics application;
refining the code and/or configurable operating parameters of the streaming analytics application based on the simulated real-time data received through the set of source operator(s) and from the pre-existing set of virtual model(s); and
creating, by the streaming analytics application, a newly-created virtual model, based on the simulated real-time data received through the set of source operator(s) and from the pre-existing set of virtual model(s).

14. The CIM of claim 13 wherein the set of pre-existing virtual model(s) includes a first virtual model corresponding to an Internet of Things (IoT) device.

15. The CIM of claim 14 wherein the first virtual model is a digital twin of a real world instantiation of an IoT device.

16. The CIM of claim 1 wherein each given virtual model of the set of pre-existing virtual model(s) is a digital twin that corresponds to a real world instantiation of a physical asset.

17. The CIM of claim 1 wherein each given virtual model of the set of pre-existing virtual model(s) is a digital twin that corresponds to a real world instantiation of a process.

18. The CIM of claim 1 wherein each given virtual model of the set of pre-existing virtual model(s) is a digital twin that corresponds to a real world instantiation of a computer system.
